(19) United States
(12) Patent Application Publication
(10) Pub. No.: US 2025/0331394 A1
(43) Pub. Date: Oct. 23, 2025

(54) LIGHT EMITTING DEVICE, DISPLAY DEVICE, IMAGE CAPTURING DEVICE, ELECTRONIC APPARATUS, AND WEARABLE DEVICE

(71) Applicant: CANON KABUSHIKI KAISHA, Tokyo (JP)

(72) Inventors: EISUKE GOMMORI, Kanagawa (JP); TAKAYUKI ITO, Kanagawa (JP); HIROAKI SANO, Tokyo (JP)

(21) Appl. No.: 19/177,760

(22) Filed: Apr. 14, 2025

(30) Foreign Application Priority Data
Apr. 19, 2024 (JP) 2024-068619

(51) Int. Cl. H10K 59/80; G02B 27/01; H04M 1/02; H10K 59/65

(52) U.S. Cl. CPC H10K 59/80518; H10K 59/65; H10K 59/879; H10K 59/8792; G02B 27/0172; G02B 2027/0178; H04M 1/0266

(57) ABSTRACT

A light emitting device including, on a substrate, a first light emitting element configured to emit visible light and a second light emitting element configured to emit an infrared ray. The first light emitting element includes a first light emitting layer, and a first reflection layer between the substrate and the first light emitting layer, the second light emitting element includes a second light emitting layer, and a second reflection layer between the substrate and the second light emitting layer. An average reflectance of the second reflection layer for visible light is lower than an average reflectance of the first reflection layer for visible light.

### BACKGROUND OF THE INVENTION

### Field of the Invention

The present invention relates to a light emitting device, a display device, an image capturing device, an electronic apparatus, and a wearable device.

### Description of the Related Art

An organic light emitting device is a device that causes a light emitting layer including an organic compound layer to emit light by applying a voltage thereto. Since the organic light emitting device is a self-light emitting device, it need not separately include a light source and a display control unit such as a shutter, like a liquid crystal display device. Accordingly, the organic light emitting device has an advantage that it can achieve a smaller thickness and less power consumption than the liquid crystal display device. Therefore, the organic light emitting device is attracting attention as an image display device for a camera viewfinder, a head mounted display, a wearable device called smartglasses, or the like.

Some of the display devices as described above detect the gazing point of a user by detecting the gaze of the user with respect to the display device, and reflect the information of the detected gaze on driving of the display device. Japanese Patent Laid-Open No. 2021-15731 (herein after PTL 1) discloses a device that detects the gaze by irradiating the eyeball of the user looking through a finder with an infrared ray, and capturing the reflected light from the eyeball by a detector.

In the display device disclosed in PTL 1, light from the display unit of the finder may enter the infrared ray emitting unit, and reflected light from the infrared ray emitting unit may deteriorate the visibility of the display unit.

### SUMMARY OF THE INVENTION

One disclosed embodiment has been made in consideration of the above-described disadvantage, and can provide a light emitting device that can reduce deterioration of display quality caused by light from a display unit being reflected by an infrared ray emitting unit.

According one aspect of the disclosure, there is provided a light emitting device. The light emitting device comprises, on a substrate, a first light emitting element configured to emit visible light and a second light emitting element configured to emit an infrared ray. The first light emitting element includes a first light emitting layer, and a first reflection layer between the substrate and the first light emitting layer. The second light emitting element includes a second light emitting layer, and a second reflection layer between the substrate and the second light emitting layer. An average reflectance of the second reflection layer for visible light is lower than an average reflectance of the first reflection layer for visible light.

Further features of the present invention will become apparent from the following description of exemplary embodiments with reference to the attached drawings.

### BRIEF DESCRIPTION OF THE DRAWINGS

FIG. 1 is a schematic view showing an example of a light emitting device according to an embodiment of the present invention;

FIG. 2 is a plan view showing an example of the light emitting device according to the embodiment of the present invention;

FIG. 3 is a sectional view showing an example of the light emitting device according to the embodiment of the present invention;

FIG. 4 is a sectional view showing an example of the light emitting device according to the embodiment of the present invention;

FIG. 5 is a sectional view showing an example of the light emitting device according to the embodiment of the present invention;

FIG. 6 is a graph showing an example of the reflectance according to the embodiment of the present invention;

FIG. 7 is a sectional view showing an example of a light emitting device according to an embodiment of the present invention;

FIG. 8 is a sectional view showing an example of a light emitting device according to an embodiment of the present invention;

FIG. 9 is a sectional view showing an example of a light emitting device according to an embodiment of the present invention;

FIG. 10 is a sectional view showing an example of a light emitting device according to an embodiment of the present invention;

FIG. 11 is a sectional view showing an example of a light emitting device according to an embodiment of the present invention;

FIG. 12 is a schematic view showing an example of a display device according to an embodiment of the present invention;

FIG. 13A is a schematic view showing an example of an image capturing device according to an embodiment of the present invention;

FIG. 13B is a schematic view showing an example of an electronic apparatus according to an embodiment of the present invention;

FIG. 14A is a schematic view showing an example of a wearable device according to an embodiment of the present invention; and

FIG. 14B is a schematic view showing an example of a wearable device according to an embodiment of the present invention.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

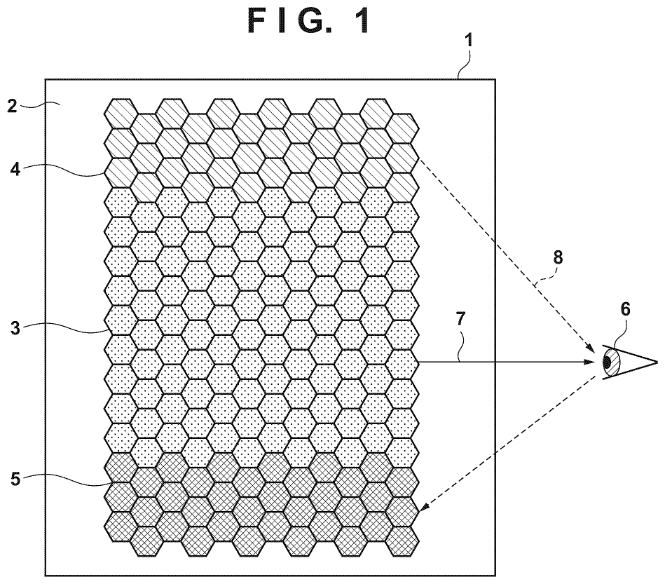

FIG. 1 is a schematic view showing the arrangement and gaze detection operation according to an embodiment of a display device according to an embodiment of the present invention. In a display device 1, a display unit 3 and an infrared ray emitting unit 4 are arranged on an insulating layer 2 provided on a substrate. The display unit forms a displayed image by emitting display light 7. On the other hand, the infrared ray emitting unit 4 emits an infrared ray 8 to an eyeball 6 of a user gazing the displayed image. When an image capturing unit 5 including light receiving elements detects reflected light of the emitted infrared ray 8 from the eyeball, a captured image of the eyeball is obtained.

Gaze detection can be performed by detecting, from the captured image of the eyeball obtained by capturing the infrared ray, the gaze of the user to the displayed image. An arbitrary known method can be applied to the gaze detection using the captured image of the eyeball. As an example, a gaze detection method based on a Purkinje image obtained by reflection of irradiation light by a cornea can be used.

More specifically, gaze detection processing based on a pupil corneal reflection method is performed. Using the pupil corneal reflection method, a gaze vector representing the direction (rotation angle) of the eyeball is calculated based on the image of the pupil and the Purkinje image included in the captured image of the eyeball 6. Thus, the gaze of the user can be detected.

At this time, if the light from the display unit enters a gaze sensing infrared ray emitting unit, reflected light is emitted. In an example, a path along which the light from the display unit enters the infrared ray emitting unit coincides a path along which the light from the display unit is reflected by the eyeball and enters the infrared ray emitting unit.

### First Embodiment

Next, an example of the arrangement of display elements and infrared ray emitting elements in a display device according to this embodiment will be described in detail. According to this embodiment, reflected light, which is emitted when light from the display unit enters the gaze sensing infrared ray emitting unit, can be reduced by setting the reflectance in the visible light region of the lower reflection layer of the infrared ray emitting unit lower than the reflectance in the visible light region of the lower reflection layer of the display unit that emits visible light.

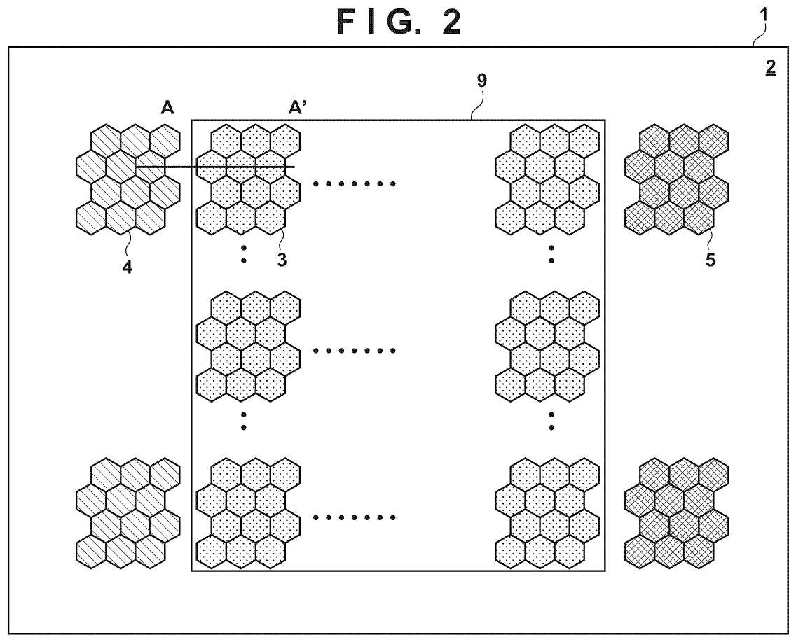

FIG. 2 is a schematic plan view of the display device according to this embodiment, in which the display unit 3 and the infrared ray emitting unit 4 are arranged on the insulating layer 2 to form a display region 9. The display unit 3 includes a display element that can emit visible light. In this specification, the display element is also referred to as a light emitting element since it emits visible light. The display unit may include an organic light emitting element that includes the first electrode, an organic compound layer including a light emitting layer, and the second electrode in this order from the insulating layer. The display unit may emit light of any color, and may emit white light. Light emission colors may be different between light emitting pixels. The region where the display unit 3 is arranged is the first light emitting region where visible light is emitted.

The infrared ray emitting unit 4 is not particularly limited in the type of the element as long as it includes an infrared ray emitting element that can emit an infrared ray. For example, an organic light emitting element, an LED element, a light emitting element containing a Perovskite material or a quantum dot (QD) material, or the like may be included. The region where the infrared ray emitting unit 4 is arranged is referred to as the second light emitting region. If the infrared ray emitting element is an organic light emitting element, it is convenient because the organic light emitting element and the infrared ray emitting element can be manufactured in the same process. If the infrared ray emitting element is an organic light emitting element, the infrared ray emitting element may include the first electrode, an organic compound layer including a light emitting layer, and the second electrode in this order from the insulating layer, similar to the display unit 3.

The image capturing unit 5 including a light receiving element only requires to include an image capturing element which is sensitive in the infrared region. For example, a photodiode, an organic photoelectric conversion element, an inorganic photoelectric conversion element, or the like may be included. The image capturing unit may be formed on the same substrate 2 as the display unit 3 and the infrared ray emitting unit 4, or may be formed as a separate member on another substrate. In order to reduce false detection due to the incident visible light, an infrared filter that transmits only an infrared ray may be provided on the image capturing element.

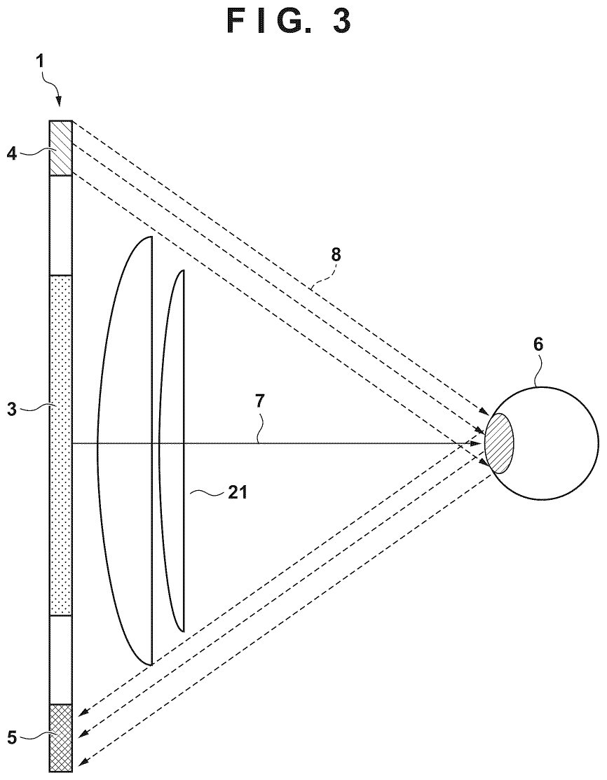

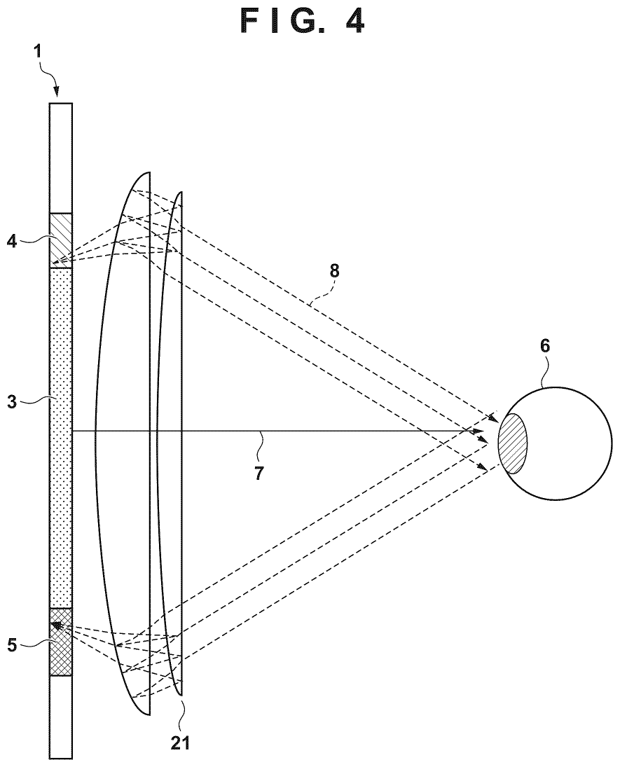

FIG. 3 shows a configuration example as an image observation device according to this embodiment. The image observation device is formed from the display device 1 and a display lens 21 serving as an eyepiece optical system. When the display light 7 is projected to the eyeball 6 of the user, the observer can observe a displayed image. Furthermore, the infrared ray reflected by the eyeball 6 of the user is converted into electrical information by the image capturing unit 5, and the gaze can be detected based on the information. In another configuration example, as shown in FIG. 4, the display light 7 and the infrared ray 8 from the display device 1 may pass through the same display lens 21 and reach the eyeball 6 of the user.

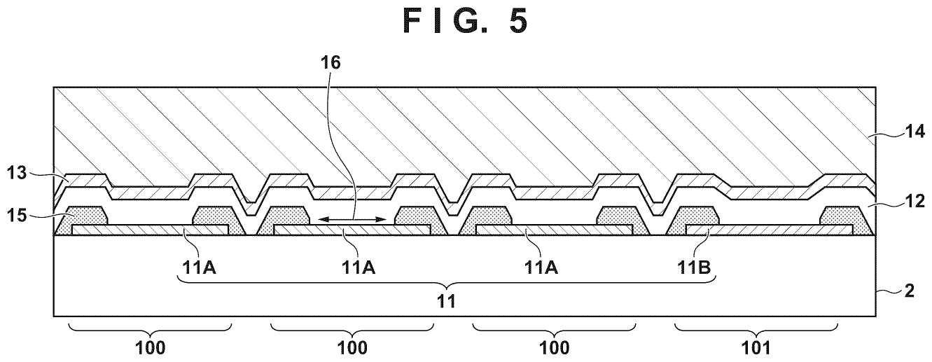

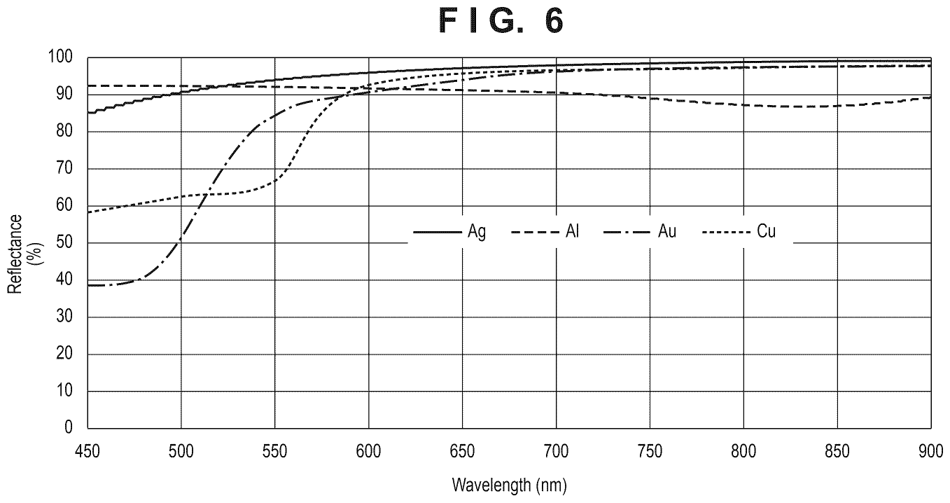

FIG. 5 is a schematic sectional view taken along a line A-A′ in FIG. 2. A light emitting element 100 shown in FIG. 5 is formed from a lower reflection layer 11A, a functional layer 12 including a light emitting layer, an upper electrode 13, and a protection layer 14 arranged on the insulating layer 2 in this order. Here, the lower reflection layer 11A can have a function as a lower electrode. Further, as shown in FIG. 5, an insulating layer 15 covering the both ends of the lower reflection layer 11A is provided. The insulating layer 15 is also called a pixel separation film or a bank.

A portion of the lower reflection layer not in contact with the insulating layer may be in contact with the functional layer. The region where the lower reflection layer 11A is in contact with the functional layer 12 is a light emitting region 16 where light is emitted when an electric field is applied between the lower reflection layer and the upper electrode. The light emitting region may be specified by measuring the distance from the end of the first insulating layer 15 covering the left end of one lower reflection layer 11A to the end of the second insulating layer 15 covering the right end of the lower reflection layer 11A. The end of the insulating layer 15 may be a contact point between the insulating layer and the lower reflection layer in FIG. 5

An infrared ray emitting element 101 is formed from a lower reflection layer 11B, the functional layer 12 including the light emitting layer, the upper electrode 13, and the protection layer 14 arranged in this order, similar to the light emitting element 100. Here, the lower reflection layer 11B can have a function as a lower electrode. Similar to the light emitting element 100, the insulating layer 15 covering the both ends of the lower reflection layer 11B is provided, and the insulating layer 15 is also called a pixel separation film or a bank.

The functional layer 12 may be constituted by a plurality of layers. If the functional layer is an organic compound layer, the plurality of layers can include a hole injection layer, a hole transport layer, an electron block layer, a light emitting layer, a hole block layer, an electron transport layer, an electron injection layer, and the like. The light emitting layer emits light when holes injected from the anode and electrons injected from the cathode recombine in the organic compound layer. The light emitting layer may have a single-layer structure or a stacked structure.

Each light emitting layer can contain one of a red light emitting material, a green light emitting material, a blue light emitting material, and an infrared ray emitting material. White light can be obtained by mixing the light emission colors. One of the light emitting layers may contain light emitting materials having a complimentary color relationship, such as a blue light emitting material and a yellow light emitting material. The material or configuration of the light emitting layer may be changed for each light emitting element to change the light emission color.

If the functional layer 12 can emit light in a wavelength region from the visible region to the infrared region, the light emitting element 100 and the infrared ray emitting element 101 may have one light emitting layer. That is, a plurality of the light emitting elements and a plurality of the infrared ray emitting elements may share one light emitting layer. Alternatively, the light emitting layer may be provided for each of the light emitting elements and infrared ray emitting elements. In this case, the light emitting layer may be patterned for each of the light emitting elements 100 and infrared ray emitting elements 101.

The upper electrode 13 may be shared by the plurality of the light emitting elements 100 and the plurality of the infrared ray emitting elements 101. That is, a common upper electrode may be formed on the entire surface of the display region 9 shown in FIG. 2.

Furthermore, the light emitting element 100 and infrared ray emitting element 101 according to this embodiment may have a so-called microcavity structure. That is, when Lr represents the optical distance from the upper surface of the lower reflection layer 11A or 11B to the light emission position of the functional layer 12, and Φr represents a phase shift when light of a wavelength λ is reflected at the interface of the lower reflection layer 11A or 11B, following equation (1) holds:

$$Lr = ( 2 m - ( Φ r / π ) ) \times ( λ / 4 ) \qquad ( 1 )$$

where m is an integer of 0 or more. The optical distance of the functional layer 12 can be optimized for each color to satisfy equation (1) described above.

If the wavelength λ satisfies equation (1), light of each color emitted by the light emitting element 100 is strengthened. However, light emitted by the light emitting element 100 or the infrared ray emitting element 101 can be strengthened even by using the wavelength λ within a range of ±λ/12. That is, in this embodiment, regarding the optical distance Lr, the optical distance Lr that is based on the relationship with the wavelength λ of light satisfying following equation (2) may be used:

$$Lr = ( 2 m - ( Φ r / π ) ) \times ( λ / 4 \pm λ / 12 ) \qquad ( 2 )$$

When Ls represents the optical distance from the light emission position of the functional layer 12 to the reflection surface of the upper electrode 13, and Φs represents a phase shift when light of the wavelength λ is reflected at the interface of the upper electrode 13, following equation (3) holds for the optical distance Ls and the wavelength λ. Note that m′ is an integer of 0 or more.

$$\begin{matrix}Lr = ( 2 {m}^{′} - ( Φ s / π ) ) \times ( λ / 4 ) \\ = - ( Φ s / π ) \times ( λ / 4 )\end{matrix} \qquad ( 3 )$$

Similar to equation (1), if the wavelength λ satisfies equation (3), light emitted by the light emitting element 100 is strengthened.

Regarding equation (3), light emitted by the light emitting element 100 can be strengthened even by using the wavelength λ within a range of ±λ/12. That is, in this embodiment, the relationship between the optical distance Ls and the wavelength λ may satisfy following equation (4):

$$\begin{matrix}Ls = ( 2 {m}^{′} - ( Φ s / π ) ) \times ( λ / 4 \pm λ / 12 ) \\ = - ( Φ s / π ) \times ( λ / 4 \pm λ / 12 )\end{matrix} \qquad ( 4 )$$

Hence, an all-layer interference L based on the optical distance Lr and the optical distance Ls substantially satisfies following equation (5). When following equation (5) holds, light of the wavelength λ is strengthened.

$$L = Lr + Ls = ( 2 m - Φ / π ) \times ( λ / 4 ) \qquad ( 5 )$$

where Φ is the sum (Φr+Φ/s) of the phase shifts when light of the wavelength λ is reflected by the interface of the lower reflection layer 11A or 11B and the interface of the upper electrode 13.

Furthermore, although light of the wavelength A satisfying equation (5) is strengthened, light emitted by the light emitting element 100 or the infrared ray emitting element 101 can be strengthened even by using the wavelength λ within a range of ±λ/12. That is, in this embodiment, the wavelength λ satisfying following equation (6) may be adopted:

$$L = Lr + Ls = ( 2 m - Φ / π ) \times ( λ / 4 \pm λ / 12 ) \qquad ( 6 )$$

The display element and the infrared ray emitting element may have different optical distances. With this arrangement, the display element can have the distance that strengthens visible light, and the infrared ray emitting element can have the distance that strengthens infrared ray emission. With the arrangement described above, it is possible that the light emitting element 100 mainly emits visible light and the infrared ray emitting element 101 emits an infrared ray while the light emitting element 100 and the infrared ray emitting element 101 share the functional layer 12.

Next, a method of reducing reflected light, which is emitted when light from the display unit enters the gaze sensing infrared ray emitting unit, in this embodiment will be described in detail with reference to FIG. 3. Here, RA_{A} and RA_{B} represent the average reflectances of the lower reflection layers 11A and 11B, respectively, for a given wavelength.

As the average reflectance RA, the average value of reflectances of a given material obtained by measuring n reflectances for a light wavelength of α nm to β nm with an increment of γ nm may be used. Here, the average reflectance RA as the average value of reflectances can be obtained from the integral value of reflectances R(λ) of the reflection layer for the defined wavelength range of α nm to β nm measured with an increment of γ nm, using equation (7):

$$RA = {\int }_{α}^{β} R ( λ ) d λ / ( \frac{( β - α )}{γ} + 1 ) \qquad ( 7 )$$

Here, RA_{A} and RA_{B} represent the average reflectances of the lower reflection layers 11A and 11B, respectively.

In order to prevent deterioration of visibility caused by the reflected light at the lower reflection layer 11B, it is effective to decrease the average reflectance in the visible light region of the lower reflection layer 11B. Here, assume that the wavelength of the visible light region is 450 nm to 700 nm. More specifically, if the average reflectance in the visible light region of the lower reflection layer 11A and the average reflectance in the visible light region of the lower reflection layer 11B shown in FIG. 3 have a relationship of RA_{A}>RA_{B}, it is possible to reduce the reflected light in the visible light region, which is emitted when light from the display unit enters the infrared ray emitting unit, and therefore it is possible to reduce deterioration of display quality.

The average reflectance RA_{B} of the lower reflection layer 11B for light in a wavelength range of 400 nm to 600 nm is preferably set lower than the average reflectance RA_{B} for light in a wavelength range of 600 nm to 900 nm. Alternatively, for the reflectance for light having a wavelength of 550 nm, a relationship of RA_{A}>RA_{B} may be set. By setting the reflectances having this relationship, it is possible to reduce the reflected light which is emitted when light from the display unit enters the infrared ray emitting unit.

Regarding RA_{B}, it is preferable that the reflectance is 70% or less for light in a wavelength range of 450 nm to 550 nm. From the viewpoint of efficiently extracting the infrared ray emitted from the infrared ray emitting unit, it is preferable that RA_{B} is higher than 70% for light in a wavelength range of 600 nm to 900 nm. By setting the reflectance RA_{B} to have the above-described values for the light wavelength of 450 nm to 550 nm and the light wavelength of 600 nm to 900 nm, it is possible to suppress deterioration of display quality and achieve highly efficient infrared ray emission. As an example of the material that can be used for the reflection layer, if a metal containing at least one of Ag and Al is adopted for the lower reflection layer 11A and a metal containing at least one of Cu and Au is adopted for the lower reflection layer 11B, each reflection layer can have appropriate reflectance.

### Second Embodiment

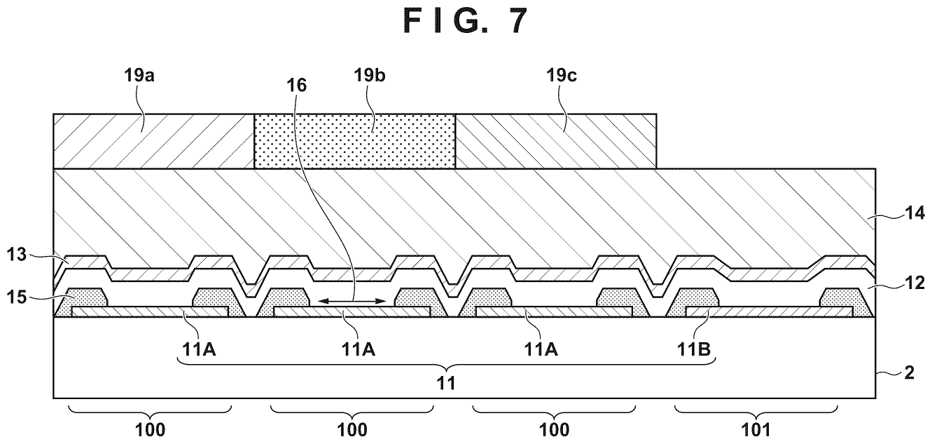

In FIG. 7, in addition to the first embodiment, color filters 19a to 19c are formed on a protection layer 14. A planarizing layer may be provided between the color filters 19a to 19c and the protection layer 14. Pixels respectively including the color filters 19a to 19c may be sub-pixels, and three sub-pixels can be regarded as one main pixel. The sub-pixels can correspond to three colors of red, green, and blue. By additive color mixing of these sub-pixels, full color display is possible. By causing light emitting from a light emitting region 16 to pass through the color filter 19, color purity can be increased.

### Third Embodiment

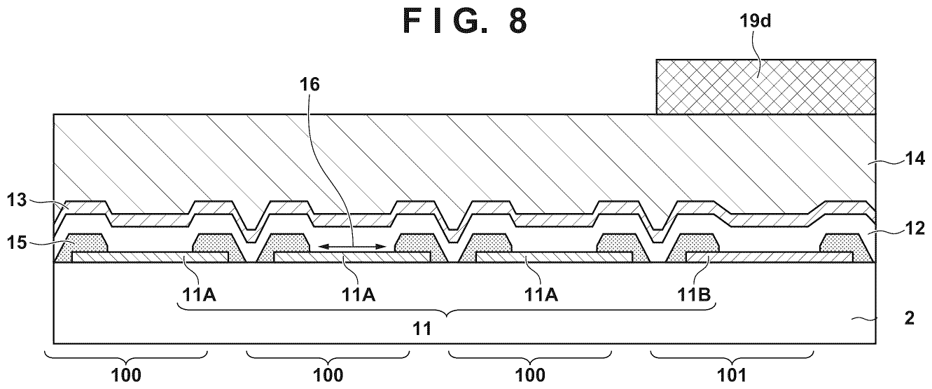

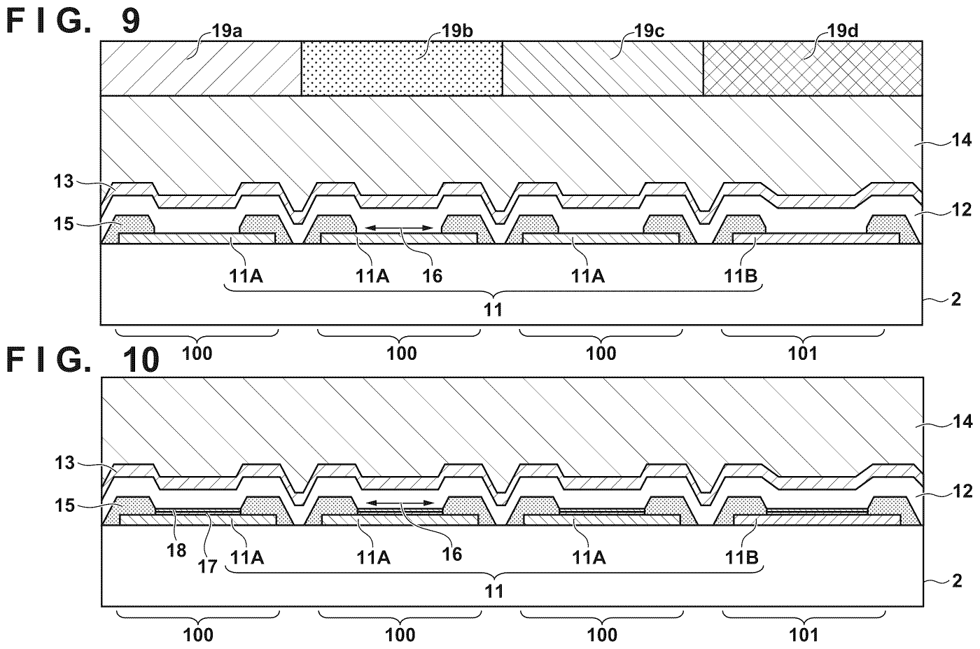

In FIG. 8, in addition to the first embodiment, a color filter 19d is formed on an infrared ray emitting element 101. In FIG. 9, in addition to the second embodiment, the color filter 19d is formed on the infrared ray emitting element 101. The color filter 19d absorbs light having a wavelength of 550 nm, so that it can suppress reflected light around the wavelength of 550 nm which has high visibility. Accordingly, deterioration of visibility caused by reflected light can be suppressed.

### Fourth Embodiment

In FIG. 10, unlike the first embodiment, a lower reflection layer 11A and a lower reflection layer 11B do not have an electrode function, and both an optical adjustment layer 17 and a transparent electrode 18 are formed on the lower reflection layer 11A and the lower reflection layer 11B. This embodiment can be applied to the second embodiment and the third embodiment.

### Fifth Embodiment

In FIG. 11, in addition to the first embodiment, a microlens 20 is formed. Here, the microlens 20 is formed in both the display unit and the infrared ray emitting unit, but may be formed in one of them. This embodiment can be applied to the above-described second to fourth embodiments.

### [Arrangement of Organic Light Emitting Element]

An organic light emitting element according to the embodiment is provided by forming an insulating layer, a lower electrode, a functional layer including a light emitting layer, and an upper electrode on a substrate. A protection layer, a color filter, a microlens, and the like may be provided on the upper electrode. If a color filter is provided, a planarizing layer can be provided between the protection layer and the color filter. The planarizing layer can be made of acrylic resin or the like. The same applies to a case in which a planarizing layer is provided between the color filter and the microlens.

### [Substrate]

At least one of quartz, glass, silicon, a resin, and a metal can be used as the material for the substrate forming the organic light emitting element. A switching element such as a transistor and a wiring may be provided on the substrate, and an insulating layer may be provided thereon. The insulating layer may be made of any material as long as a contact hole can be formed so that the wiring can be formed between the insulating layer and the first electrode and insulation from the unconnected wiring can be ensured. For example, a resin such as polyimide, silicon oxide, silicon nitride, or the like can be used.

### [Electrode]

A pair of electrodes can be used as the electrodes of the organic light emitting element. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a work function as large as possible is preferably used. For example, a metal such as gold, platinum, silver, copper, nickel, palladium, cobalt, selenium, vanadium, or tungsten, or a mixture containing some of them can be used for the anode. Alternatively, an alloy obtained by combining some of these metals, or a metal oxide such as tin oxide, zinc oxide, indium oxide, indium tin oxide (ITO), or zinc indium oxide may be used for the anode. Furthermore, a conductive polymer such as polyaniline, polypyrrole, or polythiophene can also be used for the anode.

One of these electrode materials may be used singly, or two or more of them may be used in combination. The anode may be formed by a single layer or a plurality of layers.

If the electrode of the organic light emitting element is formed as a reflective electrode, for example, chromium, aluminum, silver, titanium, tungsten, molybdenum, an alloy thereof, a stacked layer thereof, or the like can be used as the electrode material. The above materials can function as a reflective film having no role as an electrode. If the anode is used as a transparent electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function is preferably used. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used.

One of these electrode materials may be used singly, or two or more of them may be used in combination. The cathode may have a single-layer structure or a multilayer structure. Among others, silver is preferably used. To suppress aggregation of silver, a silver alloy is more preferably used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but direct current sputtering or alternating current sputtering is suitable since the good film coverage is provided and the resistance is easily lowered.

### [Pixel Separation Layer]

A pixel separation layer is formed by a silicon nitride (SiN) film, a silicon oxynitride (SiON) film, or a silicon oxide (SiO) film formed using a Chemical Vapor Deposition method (CVD method). To increase the resistance in the in-plane direction of the organic compound layer, the organic compound layer, especially the hole transport layer can be thinly deposited on the side wall of the pixel separation layer. More specifically, the organic compound layer can be deposited so as to have a thin film thickness on the side wall by increasing the taper angle of the side wall of the pixel separation layer or the film thickness of the pixel separation layer to increase vignetting during vapor deposition.

On the other hand, the pixel separation layer can be formed such that it is possible to adjust the taper angle of the side wall of the pixel separation layer or the film thickness of the pixel separation layer to the extent that no space is formed in the protection layer formed on the pixel separation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel separation layer is not acute, it is possible to effectively suppress leakage of charges to an adjacent pixel. As a result of consideration by the present inventor, it has been found that the taper angle of 60° (inclusive) to 90° (inclusive) can sufficiently reduce the occurrence of defects. The film thickness of the pixel separation layer is desirably 10 nm (inclusive) to 150 nm (inclusive). A similar effect can be obtained in a configuration including only pixel electrodes without the pixel separation layer. However, in this case, when the film thickness of the pixel electrode is set to be equal to or smaller than half the film thickness of the organic layer or the end portion of the pixel electrode is formed to have a forward tapered shape of less than 60° because short circuit of the organic light emitting element can be reduced.

### [Organic Compound Layer]

The organic compound layer of the organic light emitting element may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer can be arranged between the first and second electrodes, and may be arranged in contact with the first and second electrodes.

### [Protection Layer]

In the organic light emitting element according to the embodiment, a protection layer may be provided on the second electrode. For example, by adhering glass provided with a moisture absorbing agent on the second electrode, permeation of water or the like into the organic compound layer can be suppressed and occurrence of display defects can be suppressed. Furthermore, as another embodiment, a passivation film made of silicon nitride or the like may be provided on the cathode to suppress permeation of water or the like into the organic compound layer. For example, the protection layer can be formed by forming the cathode, transferring it to another chamber without breaking the vacuum, and forming a silicon nitride film having a thickness of 2 μm by a CVD method. The protection layer may be provided using an atomic deposition method (ALD method) after deposition using the CVD method.

The material of the film by the ALD method is not limited but can be silicon nitride, silicon oxide, aluminum oxide, or the like. A silicon nitride film may further be formed by the CVD method on the film formed by the ALD method. The film formed by the ALD method may have a film thickness smaller than that of the film formed by the CVD method. More specifically, the film thickness of the film formed by the ALD method may be 50% or less, or 10% or less.

### [Color Filter]

In the organic light emitting element according to the embodiment, a color filter may be provided on the protection layer. For example, a color filter considering the size of the organic light emitting element may be provided on another substrate, and this substrate may be bonded to the substrate with the organic light emitting element provided thereon. Alternatively, a color filter may be patterned on the above-described protection layer using a photolithography technique. The color filter can be formed from a polymeric material.

### [Planarizing Layer]

In the organic light emitting element according to the embodiment, a planarizing layer may be provided between the color filter and the protection layer. The planarizing layer is provided to reduce unevenness of the lower layer. The planarizing layer may be called a resin layer without limiting the purpose of the layer. The planarizing layer can be formed from an organic compound, and can be made of a low-molecular material or a polymeric material. However, a polymetric material is more preferable.

The planarizing layers may be provided above and below the color filter, and the same or different materials may be used for them. More specifically, examples of the material include polyvinyl carbazole resin, polycarbonate resin, polyester resin, ABS resin, acrylic resin, polyimide resin, phenol resin, epoxy resin, silicone resin, and urea resin.

### [Microlens]

The organic light emitting element can include an optical member such as a microlens on the light emission side. The microlens can be made of acrylic resin, epoxy resin, or the like. The microlens can aim to increase the amount of light extracted from the organic light emitting element and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view.

That is, among tangents contacting the semicircle of the microlens in a sectional view, there is a tangent parallel to the insulating layer, and the contact between the tangent and the semicircle is the vertex of the microlens. Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface is preferably arranged on the functional layer side of the first surface. For this configuration, the microlens needs to be formed on the light emitting element. If the functional layer is an organic layer, it is preferable to avoid a process which produces high temperature in the manufacturing step. In addition, if it is configured to arrange the second surface on the functional layer side relative to the first surface, all the glass transition temperatures of an organic compound forming the organic layer are preferably 100° C. or more, and more preferably 130° C. or more.

### [Counter Substrate]

In the organic light emitting element according to the embodiment, a counter substrate can be provided on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### [Organic Layer]

The functional layer (hole injection layer, hole transport layer, electron blocking layer, light emitting layer, hole blocking layer, electron transport layer, electron injection layer, and the like) including a light emitting layer forming the organic light emitting element according to the embodiment is formed by the method to be described below. The organic compound layer forming the organic light emitting element according to the embodiment can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them. One of these binder resins may be used singly as a homopolymer or a copolymer, or two or more of them may be used in combination. Furthermore, additives such as a well-known plasticizer, antioxidant, and an ultraviolet absorber may also be used as needed.

### [Pixel Circuit]

The light emitting device including the organic light emitting element according to the embodiment can include a pixel circuit connected to the organic light emitting element. The pixel circuit may be an active matrix circuit that individually controls light emission of the first and second organic light emitting elements. The active matrix circuit may be a voltage or current programing circuit. A driving circuit includes a pixel circuit for each pixel. The pixel circuit can include an organic light emitting element, a transistor for controlling light emission luminance of the organic light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit. The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic. The transistor forming the pixel circuit is a transistor connected to the light emitting element such as the first organic light emitting element.

### [Pixel]

The organic light emitting element according to the embodiment includes a plurality of pixels. Each pixel includes sub-pixels that emit light components of different colors. The sub-pixels include, for example, red, green, and blue emission colors, respectively. In each pixel, a region also called a pixel aperture emits light. This region is the same as the first region. The pixel aperture can have a size of 5 μm (inclusive) to 15 μm (inclusive). More specifically, the pixel aperture can have a size of 11 μm, 9.5 μm, 7.4 μm, 6.4 μm, or the like. A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. Note that, regarding the shape of the sub-pixel, for example, a shape close to a rectangle is included in a rectangle. Hence, the shape of the sub-pixel may be a shape approximated as any of the above-described known shapes. The pixel can be formed in combination of the shape of the sub-pixel and the pixel arrangement.

### Application of Light Emitting Device to Apparatus

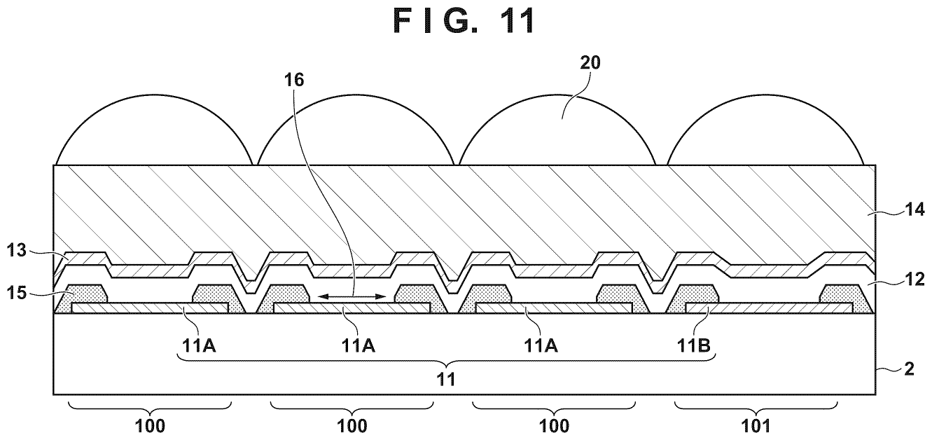

FIG. 12 is a schematic view showing an example in which the light emitting device according to the above-described embodiment is applied to a display device as an example of an electronic apparatus. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Transistors may can printed on the circuit board 1007. The battery 1008 is unnecessary if the display device is not a portable apparatus. Even when the display device is a portable apparatus, the battery 1008 may be provided at another position.

The display device according to this embodiment can include color filters of red, green, and blue. The color filters of red, green, and blue can be arranged in a delta array.

The display device according to this embodiment may be used as a display unit of a portable terminal. At this time, the display unit can have both a display function and an operation function. Examples of the portable terminal are a portable phone such as a smartphone, a tablet, and a head mounted display.

The display device according to this embodiment can be used for a display unit of an image capturing device including an optical unit having a plurality of lenses, and an image sensor for receiving light having passed through the optical unit. The image capturing device can include a display unit for displaying information acquired by the image sensor. In addition, the display unit can be either a display unit exposed outside the image capturing device, or a display unit arranged in the finder. The image capturing device can be a digital camera or a digital video camera.

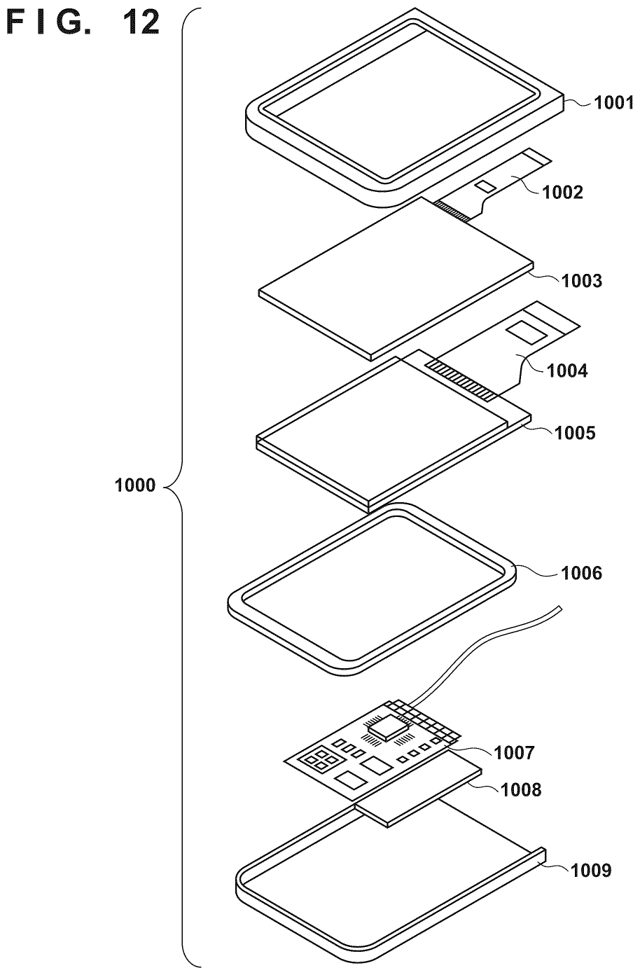

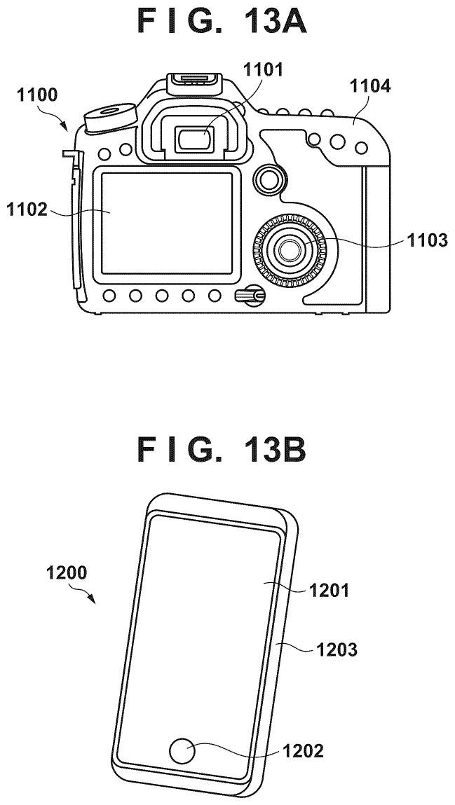

FIG. 13A is a schematic view showing an image capturing device as an example of the electronic apparatus according to this embodiment. An image capturing device 1100 can include a viewfinder 1101, a rear display 1102, an operation unit 1103, and a housing 1104. The viewfinder 1101 may include the display device to which the light emitting device according to the above-described embodiment is applied. In this case, the display device can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time, so the information is preferably displayed as soon as possible. It is therefore preferable to use the display device using the organic light emitting element according to the present invention. This is so because the organic light emitting element has a high response speed. The display device using the organic light emitting element can be used for the devices that require a high display speed more preferably than for the liquid crystal display device.

The image capturing device 1100 includes an optical unit (not shown). This optical unit has a plurality of lenses, and forms an image on an image capturing element accommodated in the housing 1104. The focal points of the plurality of lenses can be adjusted by adjusting the relative positions. This operation can also automatically be performed. The image capturing device may be called a photoelectric conversion device. The photoelectric conversion device can include, as an image capturing method, not a method of sequentially capturing images but a method of detecting the difference from a preceding image, a method of extracting an image from an always recorded image, and the like.

FIG. 13B is a schematic view showing an example of an electronic apparatus according to this embodiment. An electronic apparatus 1200 includes a display unit 1201, an operation unit 1202, and a housing 1203. The light emitting device according to the above-described embodiment can be applied to the display unit 1201. The housing 1203 can accommodate a circuit, a printed board having this circuit, a battery, and a communication unit. The operation unit 1202 can be a button or a touch-panel-type reaction unit. The operation unit can also be a biometric authentication unit that performs unlocking or the like by authenticating the fingerprint. The electronic apparatus including the communication unit can also be regarded as a communication apparatus. The electronic apparatus may also have a camera function by including a lens and an image sensor. An image captured by the camera function is displayed on the display unit. Examples of the electronic apparatus are a smartphone and a laptop computer.

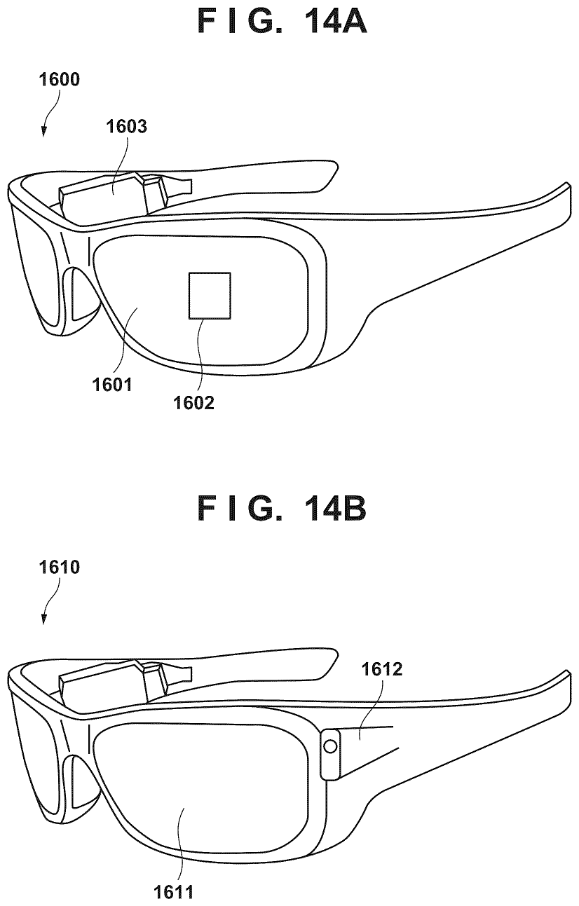

Application examples of the display device according to each embodiment described above will be described with reference to FIGS. 14A and 14B. The display device can be applied to a system that can be worn as a wearable device such as smartglasses, an HMD, or a smart contact lens. An image capturing display device used for such application examples includes an image capturing device capable of photoelectrically converting visible light and a display device capable of emitting visible light.

Glasses 1600 (smartglasses) according to one application example will be described with reference to FIG. 14A. An image capturing device 1602 such as a CMOS sensor or an SPAD is provided on the surface side of a lens 1601 of the glasses 1600. In addition, the display device to which the light emitting device according to each embodiment described above is applied is provided on the back surface side of the lens 1601.

The glasses 1600 further include a control device 1603. The control device 1603 functions as a power supply that supplies electric power to the image capturing device 1602 and the display device according to each embodiment. In addition, the control device 1603 controls the operations of the image capturing device 1602 and the display device. An optical system configured to condense light to the image capturing device 1602 is formed on the lens 1601.

Glasses 1610 (smartglasses) according to one application example will be described with reference to FIG. 14B. The glasses 1610 include a control device 1612. An image capturing device corresponding to the image capturing device 1602 and the display device are mounted on the control device 1612. The light emitting device according to each embodiment described above can be applied to the display device. An optical system configured to project light emitted from the display device in the control device 1612 is formed in a lens 1611, and an image is projected to the lens 1611. The control device 1612 functions as a power supply that supplies electric power to the image capturing device and the display device, and controls the operations of the image capturing device and the display device. The control device may include a gaze detection unit that detects the gaze of a wearer. The detection of a gaze may be done using infrared rays.

An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The gaze of the user to the displayed image is detected from the captured image of the eyeball obtained by capturing the infrared rays. An arbitrary known method can be applied to the gaze detection using the captured image of the eyeball. As an example, a gaze detection method based on a Purkinje image obtained by reflection of irradiation light by a cornea can be used.

More specifically, gaze detection processing based on a pupil corneal reflection method is performed. Using the pupil corneal reflection method, a gaze vector representing the direction (rotation angle) of the eyeball is calculated based on the image of the pupil and the Purkinje image included in the captured image of the eyeball, thereby detecting the gaze of the user.

The display device according to an embodiment of the present invention can include an image capturing device including a light receiving element, and control an image displayed on the display device based on the gaze information of the user from the image capturing device. More specifically, the display device determines a first display region at which the user is gazing and a second display region other than the first display region based on the gaze information. The first display region and the second display region may be determined by the control device of the display device, or those determined by an external control device may be received. In the display region of the display device, the display resolution of the first display region may be controlled to be higher than the display resolution of the second display region. That is, the resolution of the second display region may be lower than that of the first display region.

Alternatively, the first display region and the second display region may be determined based on the gaze information. Note that AI may be used to determine the first display region or the region of higher priority. The AI may be a model configured to estimate the angle of the gaze and the distance to a target ahead the gaze from the image of the eyeball using the image of the eyeball and the direction of actual viewing of the eyeball in the image as supervised data. The AI program may be held by the display device, the image capturing device, or an external device. If the external device holds the AI program, it is transmitted to the display device via communication.

When performing display control based on gaze detection, it can suitably be applied to smartglasses further including an image capturing device configured to capture the outside. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-068619 filed April 19,2024 which is hereby incorporated by reference herein in their entirety.

What is claimed is:

1. A light emitting device including, on a substrate, a first light emitting element configured to emit visible light and a second light emitting element configured to emit an infrared ray, wherein
the first light emitting element includes a first light emitting layer, and a first reflection layer between the substrate and the first light emitting layer,
the second light emitting element includes a second light emitting layer, and a second reflection layer between the substrate and the second light emitting layer, and
an average reflectance of the second reflection layer for visible light is lower than an average reflectance of the first reflection layer for visible light.

2. The device according to claim 1, wherein a light receiving element is provided on the substrate.

3. The device according to claim 1, wherein an average reflectance of the second reflection layer for light having a wavelength of 450 nm to 550 nm is lower than an average reflectance of the second reflection layer for light having a wavelength of 600 nm to 900 nm.

4. The device according to claim 1, wherein an average reflectance of the second reflection layer for light having a wavelength of 450 nm to 550 nm is not more than 70%, and an average reflectance of the second reflection layer for light having a wavelength of 600 nm to 900 nm is higher than 70%.

5. The device according to claim 1, wherein a reflectance of the second reflection layer for light having a wavelength of 550 nm is lower than a reflectance of the first reflection layer for light having a wavelength of 550 nm.

6. The device according to claim 1, wherein a filter configured to absorb light having a wavelength of 550 nm is provided on a light extraction side of the second light emitting element.

7. The device according to claim 1, wherein a microlens is arranged on a light extraction side of at least one of the first light emitting element and the second light emitting element.

8. The device according to claim 1, wherein at least one of the first light emitting layer and the second light emitting layer contains an organic compound.

9. A light emitting device including, on a substrate, a first light emitting element configured to emit visible light and a second light emitting element configured to emit an infrared ray, wherein
the first light emitting element includes a first light emitting layer, and a first reflection layer between the substrate and the first light emitting layer,
the second light emitting element includes a second light emitting layer, and a second reflection layer between the substrate and the second light emitting layer, and
the first reflection layer contains at least one of silver and aluminum, and the second reflection layer contains at least one of copper and gold.

10. The device according to claim 9, wherein a light receiving element is provided on the substrate.

11. The device according to claim 9, wherein the first reflection layer and the second reflection layer are electrodes configured to apply a voltage to the first light emitting layer and the second light emitting layer, respectively.

12. The device according to claim 9, wherein a filter configured to absorb light having a wavelength of 550 nm is provided on a light extraction side of the second light emitting element.

13. The device according to claim 9, wherein a microlens is arranged on a light extraction side of at least one of the first light emitting element and the second light emitting element.

14. The device according to claim 9, wherein at least one of the first light emitting layer and the second light emitting layer contains an organic compound.

15. An image capturing device comprising an optical unit including a plurality of lenses, an image capturing element configured to receive light having passed through the optical unit, and a display unit configured to display an image captured by the image capturing element,
wherein the display unit includes a light emitting device defined in claim 1.

16. A display device comprising a display unit including a light emitting device defined in claim 1, and a housing provided with the display unit.

17. An electronic apparatus comprising a display unit including a light emitting device defined in claim 1, a housing provided with the display unit, and a communication unit provided in the housing and configured to perform external communication.

18. A wearable device comprising a display device configured to display an image,
wherein the display device includes a light emitting device defined in claim 1.
